(19) United States
(12) Patent Application Publication
(10) Pub. No.: US 2007/0058422 A1
(43) Pub. Date: Mar. 15, 2007

(54) Programmable magnetic memory device

(75) Inventors: Gavin Nicholas Phillips, Eindhoven (NL); Kars-Michiel Hubert Lenssen, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONNINKLIJKE PHILIPS ELECTRONICS N.V. GROENEWOUDSEWEG 1, 5621 BA EINDHOVEN (NL)

(21) Appl. No.: 10/529,685

(22) PCT Filed: Sep. 30, 2003
(86) PCT No.: PCT/IB03/04315

§ 371 Date: Mar. 29, 2005

(30) Foreign Application Priority Data
Oct. 3, 2002 (EP) 02079081.2
May 23, 2003 (EP) 03101501.9

(51) Int. Cl. G11C 11/00

(52) U.S. Cl. 365/158

(57) ABSTRACT

A memory device has an information plane (32) for storing data bits in a magnetic state of an electro-magnetic material at an array of bit locations (31). The device further has an array of electro-magnetic sensor elements (51) that are aligned with the bit locations. The information plane (32) is programmable or programmed via a separate writing device (21). The writing device provides at least one beam of radiation (26) for heating the electro-magnetic material at the bit locations to a programming temperature. The magnetic state of the bit locations is programmed by applying a magnetic field during said heating of selected bit locations via the beams of radiation. Hence the memory device provides a magnetic read-only memory (MROM) that cannot be (re-)programmed without the proper writing device.

The invention relates to a memory device comprising an information plane comprising an electromagnetic material constituting an array of bit locations, a magnetic state of said material at a bit location representing the value thereof, and an array of electro-magnetic sensor elements that are aligned with the bit locations.

The invention further relates to a writing device for programming a memory device.

The invention further relates to a method of manufacturing a memory device.

A magnetic random access memory (MRAM) is known from the article: “Curie point written magnetoresistive memory” by R. S. Beech et. al., Journal of Applied Physics, Volume 87, Number 9, 1 May 2000. In general MRAM devices have an array of bit cells, the bits cells having an electronic sensor element and a bit location constituted by a free magnetic layer. The magnetic state of the material of the free magnetic layer is programmable and represents the value of the bit location. In a read mode the sensor element is arranged for detecting the magnetic state, in particular via a tunneling magneto-resistive effect (TMR). Current is guided via a tunneling barrier wherein the tunnel probability is influenced by the magnetic state, resulting in a change of the resistance of the sensor element. In a program (or write) mode a strong program current is guided via a programming circuit and causes a magnetic field strong enough to set the magnetic state at the respective bit location to a predefined value in accordance with the direction of the programming magnetic field and program current. It is to be noted that MRAM is a non-volatile memory type, i.e. the value of the bit locations does not change if the device is with or without operating power. Hence the MRAM device is suitable for devices that need to be active shortly after power-on. In said article a procedure, called Curie point writing (CPW), for writing the bit locations at a programming temperature well above the operational working temperature is described. The Curie temperature is a characteristic value for a magnetic material at which the spontaneous magnetization becomes zero. The bit cells have a magnetic storage material at the bit locations typically comprising a storage film of NiFe and a pinning layer of FeMn.

It is noted that the CPW cell has a pinned storage film. The cell is heated by joule heating due to current pulses through the memory cell and via current conductors such as a word line. The temperature is raised above the Néel temperature of the pinning layer. The Néel temperature is a critical temperature for an (antiferromagnetic) material below which the atomic moments are arranged parallel and antiparallel to a preferred direction. The magnetic field generated by the word line current sets the pinning direction depending on the polarity of the current. It is noted that the bits are stored in the magnetically hard component (the pinning layer) and are sensed (nondestructively) by switching the soft component (top layer), as further described in the article “Design, simulation and realization of solid state memory element using the weakly coupled GMR effect” by Zhi Gang Wang and Yoshihisa Nakamura; IEEE Transactions on Magnetics, Vol. 32, No. 2, March 1996. A problem of the known device is that the value of the bit locations has to be programmed by applying the program current for each individual bit cell.

Therefore it is an object of the invention to provide a storage system that has an efficient way of programming the value of the bit locations.

According to a first aspect of the invention the object is achieved with a memory device as defined in the opening paragraph, characterized in that the magnetic state of said material is programmable or programmed via a separate writing device for providing at least one beam of radiation for heating the electromagnetic material at the bit locations to a programming temperature.

According to a second aspect of the invention the object is achieved with a writing device for programming the memory device, the writing device comprising a programming surface for cooperating with the information plane of the memory device, and heating means for generating at least one beam of radiation for heating the electromagnetic material at the bit locations to a programming temperature.

According to a third aspect of the invention the object is achieved with a method of manufacturing a memory device, the method comprising programming the device by heating the electromagnetic material at the bit locations to a programming temperature via at least one beam of radiation provided by a separate writing device, and setting the magnetic state of the electromagnetic material at the bit locations according to predefined data.

The effect of programming the magnetic state of the material at the bit locations using an external writing device is that for a user the contents of the device are immediately available. The memory device may be used for distributing software content which is programmed during manufacture. This has the advantage that data can be accessed immediately. Further there is a protection against reprogramming the device, or copying the content to a similar storage device, because the user may not have access to a writing device. In addition heating of the bit locations or the strength of the magnetic field used for programming is not limited by a maximum current through thin on-chip metal lines. Hence at working temperature the magnetic material can be highly stable. This has the advantage that small memory cells are possible, or that such a memory device can be used in environments with strong external magnetic fields.

The invention is also based on the following recognition. The known magnetic storage device is a solid state device that contains magnetic material in the bit cells that is set to a magnetic state for storing data bits. The isolated patches of material are situated at a specific depth level with respect to the top (or bottom) surface of a substrate (called die) on which the device is formed. The inventors have seen that the combined patches of material can be considered to constitute a single information plane. In the known solid state device the information plane is not accessible, and programming necessarily has to be performed by the bit cell element itself. By providing access to the information plane, the material at the bit locations may be set to a defined magnetic state by heating the bit locations to a programming temperature by an external radiation beam provided by a separate writing device. Optical elements, e.g. an array of lasers, generate heat in the cells to be programmed. A magnetic field, provided either by the writing device or by currents in the elements of the memory device, sets the magnetic state of the material in the bit cell to the required value.

It is noted that alignment is required to bring the interface surface of the writing device opposite to the bit locations at a required working distance. For example, the external writing may be applied during manufacture of the die (when the material constituting the information plane is not yet covered) or after finishing the die and before encapsulation the die in a housing. Alternatively the external writing is made possible by a special housing for the device that allows close contact between the writing device and the information plane, and has elements for aligning the bit locations with the beam or multitude of beams.

In an embodiment the device comprises a housing for encapsulating the array of electromagnetic sensor elements, which housing has a protective cover for preventing heating bit locations for changing said magnetic state, in particular the protective cover being a sliding cover. This has the advantage that the user cannot accidentally or on purpose change the contents of the device. Further such a device can be cheaper and/or of a higher bit density, because the writing circuitry which needs relatively large currents and write components within the sensor element can be left out.

In an embodiment of the device the sensor elements comprise a second magnetic material for constituting a reference layer having a predetermined magnetic state, the second magnetic material having a second Néel temperature that is substantially higher than a first Néel temperature of the electromagnetic material constituting an array of bit locations for allowing said programming at the programming temperature near the first Néel temperature without affecting the predetermined magnetic state of the second magnetic material. This has the advantage that the magnetic state of the second material remains fixed constituting a hard magnetic reference, while the magnetic state of the first magnetic material represents the value of the bit location constituting a soft memory layer. Hence the read-out of the magnetic state is straightforward, and does not require switching of a soft magnetic layer as indicated in the introduction for the CPW memory cell.

In an embodiment the device comprises a heat sink element near the bit locations for reducing heating of bit locations adjacent to a bit location that is heated for programming. This has the advantage that bit locations, which are not to be programmed but are adjacent to a bit location that is being heated for programming, will be at a lower temperature, and hence the risk of inadvertently changing the magnetic state of such bit locations is reduced.

Further preferred embodiments of the device according to the invention are given in the dependent claims.

These and other aspects of the invention will be apparent from and elucidated further with reference to the embodiments described by way of example in the following description and with reference to the accompanying drawings, in which:

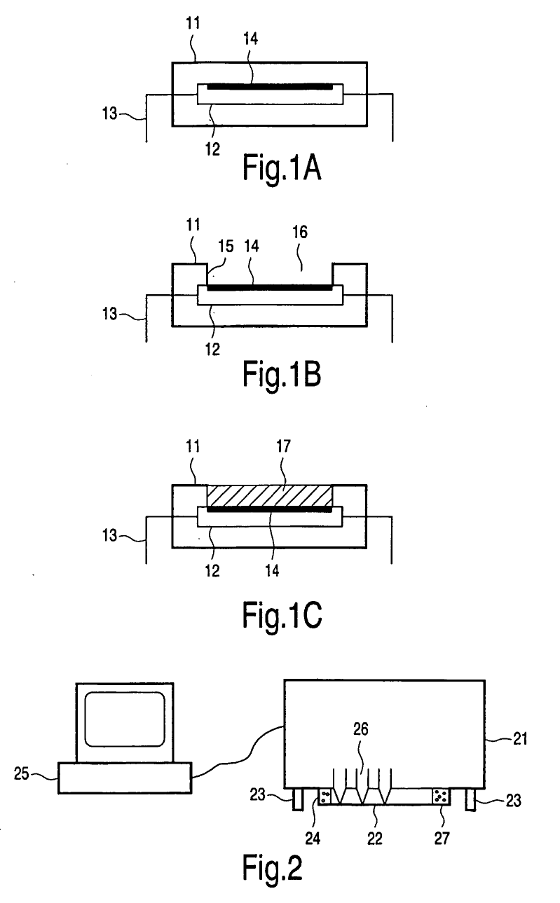

FIG. 1a shows a programmed storage device,

FIG. 1b shows a programmable storage device having an interface surface,

FIG. 1c shows a programmable storage device having a protective cover,

FIG. 2 shows a writing device for programming a storage device,

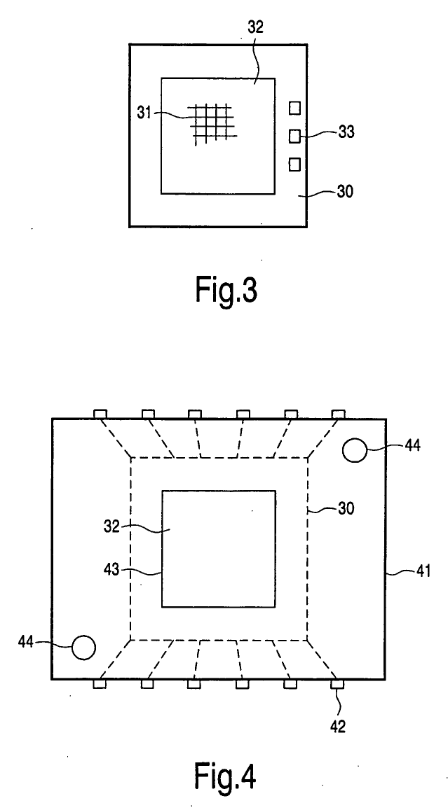

FIG. 3 shows a storage device (top view),

FIG. 4 shows an encapsulated storage device,

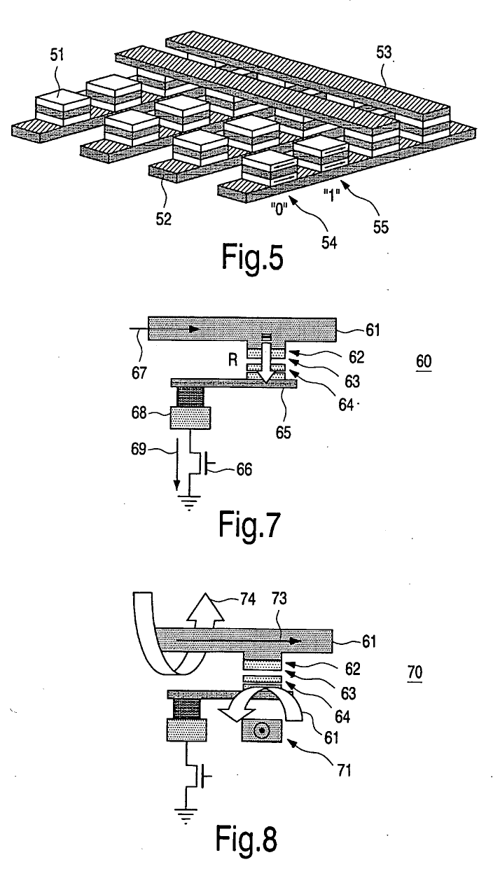

FIG. 5 shows an array of sensor elements,

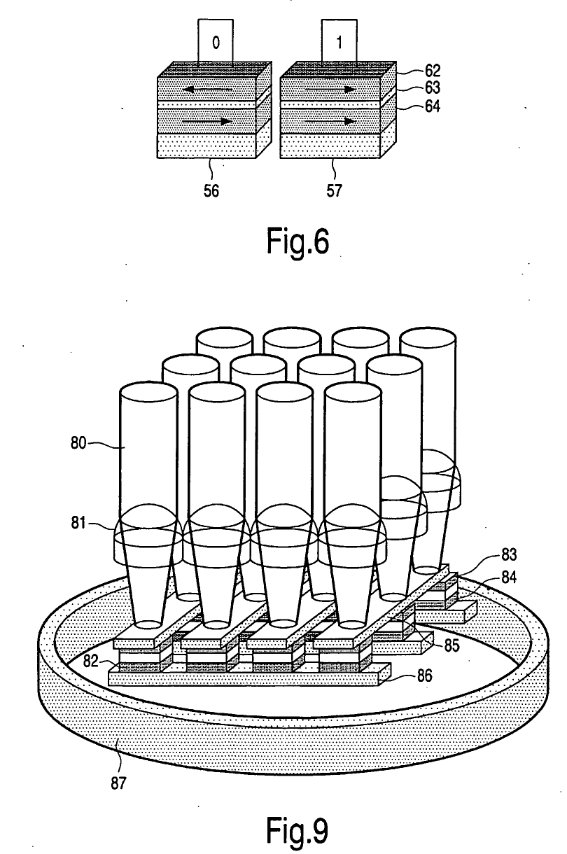

FIG. 6 shows a memory cell in two magnetic states,

FIG. 7 shows a read-only sensor element in detail,

FIG. 8 shows a read/write element in write mode.

FIG. 9 shows an optical programming device,

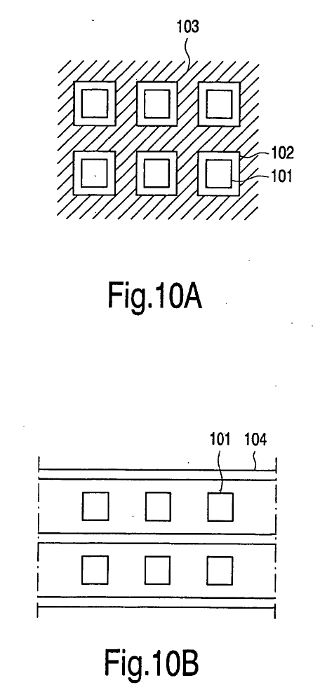

FIG. 10a shows a memory device having a heat sink layer, and

FIG. 10b shows a memory device having heat sink elements.

In the FIGS. elements which correspond to elements already described have the same reference numerals.

FIG. 1 a shows a programmed storage device. The device has a housing 11 containing a memory device 12. The memory device 12 has an array of bit cells for storing data bits in a corresponding array of bit locations. An electromagnetic material is present at the bit locations. The magnetic state of said material at a bit location represents the logical value thereof The array of bit locations constitutes an information plane 14. Each bit cell has an electromagnetic sensor element operating on said material at the corresponding bit location, e.g. a read-only cell as described below with FIG. 7 or a read-write cell as described below with FIG. 8. The sensor elements and further electronic circuitry are made on a substrate material forming a so-called die by techniques well known from semiconductor manufacture, such as MRAM chips. The die is provided with electrical connections to leads 13 that provide coupling to any electrical circuit outside the housing. The information bits are represented by magnetized states of the material in the bit cells, for example the free layers in the spin-tunnel junctions, similar to normal MRAM. This enables to make a factory-programmable read-only memory that is fully MRAM-compatible.

The programming of the memory has been done by applying external heating to the bit locations to be programmed in combination with a magnetic field, e.g. at the end of the IC-production. The information plane 14 is programmed via a separate writing device before encapsulating the memory device 12 in the housing 11. Thereto the die (at an intermediate state of its production) is positioned at a programming interface of the separate writing device. The programming interface has an array of radiation generators that generate controllable radiation beams at each bit location in the information plane. A first magnetic field may be generated for use in a first step programming bit locations to a first magnetic state representing a logical value 0 and a second field in an opposite direction for in a second step programming the bit locations to a second magnetic state representing a logical value 1. The field is strong enough to set the magnetic state of the material at the bit location to a specific value while the magnetic material is heated to a programming temperature, in particular a temperature near the Curie temperature or the Noel temperature for antiferromagnetic material as explained below. The magnetic fields may also be generated by currents passing through conductors on the die itself, while the heating of the bit locations is provided by the external writing device.

It is noted that positioning the writing device with respect to the die includes aligning the radiation generators opposite the bit cells of the memory device. In an embodiment of the programming step during manufacture the positing is controlled by reading a signal from bit cells of the memory device, for example by verifying the signal against the data to be programmed.

FIG. 1b shows a programmable storage device having an interface surface. The device has a housing 11 containing a memory device 12, which housing generally corresponds to the housing described with FIG. 1a. In the embodiment shown in FIG. 1b the housing 11 is provided with an opening 16 for receiving an external programming device. The opening has precisely shaped side walls 15 acting as mechanical alignment for positioning a programming surface of the programming device over the information plane 14, and achieving a one to one alignment of the bit locations and the field generator elements in the programming surface. The information plane is exposed to the outside world. In an embodiment the information plane is covered by a protective layer or by a removable cover part (not shown) that fits into the opening 16 when programming is not required. In an embodiment the cover is a slidable cover that slides in the cavity provided by the side walls 15.

FIG. 1c shows a programmable storage device having a protective cover. The device has a housing 11 containing a memory device 12 and generally corresponds to the device described with FIG. 1a. In the embodiment shown in FIG. 1c the housing 11 is provided with a fixed protective cover 17 for preventing any programming or changing said magnetic state at the bit locations via heating the bit locations via an external heating source such as a radiation beam. In an embodiment the protective cover 17 is provided with a magnetically shielding material for effectively magnetically shielding the information plane. It is noted that the protective cover can be put in position during initial encapsulation, of course after programming the device as described with reference to FIG. 1a. Alternatively the housing as shown in FIG. 1b having an opening is used, and the opening is closed later, e.g. after the device has been mounted on a printed circuit board and has been programmed by an equipment manufacturer.

FIG. 2 shows a writing device for programming a storage device. A programming unit 21 has a programming surface 22 for interfacing with the information plane of the memory device. The programming unit may be stand-alone or may be coupled to a programming system 25, for example a computer running suitable programming software. An array of radiation generators is placed immediately behind the programming surface 22. Each radiation generator 26 generates a controllable beam of radiation at the programming surface for heating the electromagnetic material at the corresponding bit location opposite that generator. A detailed embodiment is described with reference to FIG. 9.

In an embodiment a homogenous magnetic field could be applied that is not sufficiently strong to reverse bits at room temperature; then the bits to be written are locally heated by exposure to a heat source via a mask, e.g. a mask having holes correlating with the bit locations that should be written. In a first step 0's are written, then the process is repeated with an opposite field direction for the 1's. In particular two different masks should be used subsequently with opposite magnetic fields (e.g. first write all 0's, then all 1's). Alternatively in a first step all bit location could be reset (e.g. all 0's written) by a strong homogeneous magnetic field, with or without heating the bit locations, and subsequently only the bits at specific locations where 1's are desired are reversed.

In an embodiment the writing device has a magnetic field generator 27 for generating a magnetic field at the bit locations, for example a coil or a permanent magnet. A single permanent magnet may be used for a device that is able to program bit locations to only a single state, e.g. after resetting all bit locations to a different, opposite magnetic state in a preceding step.

In an embodiment the programming surface 22 is positioned on a protruding portion having precisely shaped walls 24 for acting as mechanical alignment for positioning the programming surface 22 over an information plane 14 of a device to be programmed. The aligning is required to achieve a one to one alignment of the bit locations and the field generator elements in the programming surface. In an embodiment the programming unit has alignment pins 23 for cooperating with precisely shaped holes in a memory device.

It is noted that various other alignment means can be easily designed, for example an active alignment using a few actuators for moving the memory device with respect to the programming surface until optimal alignment has been achieved. In an embodiment misalignment is detected by providing electronic means to recognize the location of the memory device with respect to the writer. This can be done by pattern recognition and matching with a known pattern. In an embodiment the alignment is measured by a signal derived from the sensor elements in the memory device, or by a special sensor element outside the array that is adapted to detect an alignment magnetic field generated by the programming device on a predefined location with respect to the programming surface. Alternatively optical marks are provided on the memory device and are detected by optical sensors in the writing device.

FIG. 3 shows a storage device (top view). A memory device 30 is constituted by a die containing electronic circuitry and an array 31 of bit cells. The device 30 is intended to interface with the writing device described above. Thereto the device has an interface surface 32 that accommodates the array 31. The array is a two-dimensional layout of electro-magnetic sensor units including a magnetic material constituting the information plane. Further the die is provided with bonding pads 33 for connecting to the external world, e.g. via wires and leads.

FIG. 4 shows an encapsulated storage device. The memory device 30 is encapsulated in a housing 41. External leads 42 are provided for connecting the device to electronic circuits on a printed circuit board. The external leads 42 are connected via wires to bonding pads on the memory device 30 (shown in dashed lines). The storage device has an opening 43 exposing the interface surface 32 of the memory device 30 for cooperating with a programming device as described above. In an embodiment the housing has precisely shaped holes 44 for cooperating with guiding pins of the programming device.

FIG. 5 shows an array of sensor elements. The array has sensor elements 51 in a regular pattern of rows. The elements of a row are coupled by shared bit lines 53, while in columns the elements share word lines 52. Each sensor element shown has a multilayer stack. A sensor element 54 is shown having opposite magnetic states in layers of the multilayer stack for representing the configuration when measuring a bit location with a logic value 0. A sensor element 55 is shown having equal magnetic states in layers of the multilayer stack for representing the configuration when measuring a bit location with a logic value 1. The direction is detected in sensor elements having a multilayer or single layer stack by using a magneto-resistive effect, for example GMR, AMR or TMR. The TMR type sensor is preferred for resistance matching reasons for the sensor element. While the given examples use magnetoresistive elements with in-plane sensitivity it is also possible to use elements that are sensitive to perpendicular fields. For a description of sensors using these effects refer to

“Magnetoresistive sensors and memory” by K.-M. H. Lenssen, as published in “Frontiers of Multifunctional Nanosystems”, page 431-452, ISBN 1-4020-0560-1 (HB) or 1-4020-0561-X (PB). Basic magnetic effects such as antiferromagnetism are described for example in the book ‘Solid State Magnetism’ by John Crangle; ISBN 0-340-54552-6, in particular in chapters 1.1, 6.1 and 6.2.

For the representation of the bits there exist different possibilities. So-called pseudo-spin valves comprise two ferromagnetic layers that switch their magnetization direction at different magnetic fields; this can be accomplished by using layers of different magnetic materials, or layers of the same material but of different thickness. In another embodiment exchange-biased spin-tunnel junctions are used, wherein the magnetization direction of one of the magnetic layers is so rigid that it can be considered fixed under normal operation conditions. This can, for example, be achieved by using exchange biasing or an artificial antiferromagnet.

In the sensor element the read-out is done by a resistance measurement which relies on a magnetoresistance (MR) phenomenon detected in a multilayer stack. Sensor elements can be based on the anisotropic magnetoresistance (AMR) effect in thin films. Since the amplitude of the AMR effect in thin films is typically less than 3%, the use of AMR requires sensitive electronics. The larger giant magnetoresistance effect (GMR) has a larger MR effect (5 to 15%), and therefore a higher output signal. Magnetic tunnel junctions use a large tunneling magnetoresistance (TMR) effect, and resistance changes up to ≈50% have been shown. Because of the strong dependence of the TMR effect on the bias voltage, the useable resistance change in practical applications is at present around 35%. In general, both GMR and TMR result in a low resistance if the magnetization directions in the multilayer stack are parallel and a high resistance when the magnetizations are oriented antiparallel. In TMR multilayers the sense current has to be applied perpendicular to the layer planes (Current Perpendicular to Plane, CPP) because the electrons have to tunnel through the barrier layer; in GMR devices the sense current usually flows in the plane of the layers (Current IN Plane, CIP), although a CPP configuration might provide a larger MR effect, but the resistance perpendicular to the planes of these all-metallic multilayers is very small. Nevertheless, using further miniaturization, sensors based on CPP and GMR are possible.

FIG. 6 shows a memory cell in two magnetic states. The memory cell has a layer stack having on top a memory layer 62 that can be programmed to two different magnetic states. Next a tunneling barrier 63 and a fixed magnetic layer 64, usually called reference layer, are provided. In a first state 56 the magnetic direction in the memory layer is opposite to the magnetic direction in the reference layer. In a second state 57 the magnetic direction in the memory layer is parallel to the magnetic direction in the reference layer. The reference layer 64 has a fixed magnetization, whereas the magnetization of the memory layer 62 may be switched by the application of a magnetic field. A parallel alignment of the magnetizations of the two layers corresponds to one logical state (e.g. 1) while an anti-parallel alignment corresponds to the opposite logical state (e.g. 0). Read-out is via the measurement of the resistance of the multilayer stack when a current is passed perpendicular to the interface between the layers such that electron tunneling occurs through the non-magnetic layer. A parallel alignment of the layer magnetizations results in a low resistance, and an anti-parallel alignment a (typically 50%) higher resistance.

In an embodiment the memory cell has a layer stack having an RE-TM/tunnel barrier/RE-TM magnetic tunnel junction (MTJ); RE-TM being a magnetic material having a sub-lattice of Rare Earth and a sub-lattice of Transition Metal. Both RE-TM layers have a high coercivity at room temperature, the lower reference layer possessing the highest Néel (Curie) temperature. The magnetization of the reference layer is fixed whereas the magnetization of the upper layer may be reversed via a thermo-magnetic process combining the application of a heat source (e.g. focused laser beam) and a magnetic field. The heat and possibly also an external magnetic field source are housed in dedicated programming apparatus separate from the memory device as described above with reference to FIG. 2. The memory device contains only the MTJ stack and associated electronics and conductors for readout.

Suitable materials for the RE-TM layers are TbFeCo and GdFeCo magnetic layers. Such materials typically exhibit perpendicular magnetic anisotropy and magnetic characteristics that vary rapidly with both temperature and atomic composition. The advantage of using such materials in the memory cell is that the high intrinsic magnetic anisotropies of the magnetic materials used results in the possibility of using smaller magnetic elements and therefore increasing the density (memory capacity) of the cells. In principle any magnetic material with a large perpendicular magnetic anisotropy can be used, including materials as Co/Pt, Co/Pd, CoNi/Pt multilayers or e.g. CoNiPt alloys. The materials suitable for use as memory and reference layers are not restricted to RE-TM alloys, or materials exhibiting perpendicular magnetic anisotropy. Other materials include multilayers of Co (and/or Ni) and/or Pt, Pd, Ag or Au possessing perpendicular or in-plane magnetic anisotropy; alloys containing CoCrPt, CoNiPt, FePt, or NiFe possessing perpendicular or in-plane magnetic anisotropy, or any materials combination commonly used for magnetic tunnel junctions or (giant) magneto-resistive devices. It is noted that the magnetization of the reference layer may be stabilized via direct, or indirect (through further magnetic layers) exchange coupling to another magnetic film or structure, such as an artificial anti-ferromagnet (AAF) or an intrinsic anti-ferromagnet.

FIG. 7 shows a read-only sensor element in detail. The read-only sensor element 60 is of the read-only type that is able to read, but not to alter, the value of a bit cell. The element has a bit line 61 of an electrically conductive material for guiding a read current 67 to a multilayer stack of layers of a free magnetic layer 62, a tunneling barrier 63, and a fixed magnetic layer 64. The stack is built on a further conductor 65 connected via a selection line 68 to a selection transistor 66. The selection transistor 66 couples the read current indicated by arrow 69 to ground level for reading the respective bit cell resistance when activated by a control voltage on its gate. The magnetization directions present in the fixed magnetic layer 64 and the free magnetic layer 62 determine the resistance in the tunneling barrier 63, similar to the bit cell elements in an MRAM memory. The magnetization in the free magnetic layer is determined during programming by the external writing device by heating the material to a programming temperature near the Néel temperature and applying an external magnetic field in the desired direction, and subsequently cooling the material. It is noted that the field may be removed before the actual cooling of the material starts if the heating is accurately controlled and the temperature of the material is at a predefined level a little below the Néel temperature.

FIG. 8 shows a read/write element in write mode. The read-write element 70 has the same components as the read-only element 60 described above with reference to FIG. 7, and in addition a write line 71 for conducting a relatively large write current for generating a first write field component 72. Via bit line 61 a second write current 73 is guided for generating a second write field component 74. The combined field generated by both write currents is strong enough to set the magnetic state in the free magnetic layer 62, when the material is heated to a programming temperature near the Néel temperature by an external programming device. Writing a certain cell is equivalent to setting a magnetization in the desired direction, for example, magnetization to the left means ‘0’ and magnetization to the right means ‘1’. By applying a current pulse to a bit line and a word line a magnetic field pulse is induced. Only the cell in the array at the crossing point of both lines experiences the maximum magnetic field (i.e. the vectorial addition of the fields induced by both current pulses) and its magnetization is reversed; all other cells below the bit or word line are exposed to the lower field that is caused by a single current pulse and will therefore not change their magnetization directions.

The electromagnetic sensor elements are provided with electrical conductors for conducting read and/or write currents. In an embodiment the conductors are provided with current limiting means for preventing the applications of currents of sufficient magnitude to generate magnetic fields of the necessary magnitude for setting the magnetic state at the corresponding bit location without the proper heating of that bit location to the programming temperature. By intentionally guiding large currents to a bit location a malignant user may try to heat that bit location. In an alternative embodiment the currents are limited for preventing heating of the electromagnetic material at the bit locations to a temperature near the programming temperature.

The current conducting capability of the lines to the bit cells may be limited by having a relatively high resistance. High voltages required to generate the higher currents cannot be applied without destroying the electronic circuits in the device. Alternatively the currents may be limited by inserting electronic current control circuits, or by inserting a fuse that blows at currents above operational values. The current through the word and bit lines is limited by the fuse that breaks the connection between current source and word or bit line, should the current rise above a certain value, i.e. currents lying between operational currents required for low noise resistance measurements and currents required to heat the bit location or generate a magnetic field large enough to switch the memory layer. Such a current limiting device may break the electrical connection permanently should the memory device be required to become unusable on attempted un-authorized re-programming.

The memory device according to the invention is in particular suitable for the following applications. The read-only type can be used instead of mask-ROM that would require its contents already in the mask design. This has the advantage that the content can be programmed “in the last moment of the production”. Further types of One-Time-Programmable memory can also be replaced, with the advantage that the new device can be programmed more than once (so that already programmed memories can be updated or corrected and do not become outdated). A further application is a portable device that needs exchangeable memory, e.g. a laptop computer or portable music player. The storage device has low power consumption, and instant access to the data. The device can also be used as a storage medium for content distribution. A further application is a smartcard. Also the device can be applied as secure memory that cannot be rewritten after the production, e.g. as a memory that has to store data that are unique for every individual IC (e.g. a unique identification number or a counter or a random secret code etc.).

In an embodiment a number of sensor elements are read at the same time. The addressing of the bit cells is done by means of an array of crossing lines. The read-out method depends on the type of sensor. In the case of pseudo-spin valves a number of cells (N) can be connected in series in the word line, because the resistance of these completely metallic cells is relatively low. This provides the interesting advantage that only one switching element (usually a transistor) is needed per N cells. The associated disadvantage is that the relative resistance change is divided by N. The read-out is done by measuring the resistance of a word line (with the series of cells), while subsequently a small positive plus negative current pulse is applied to the desired bit line. The accompanying magnetic field pulses are between the switching fields of the two ferromagnetic layers; thus the layer with the higher switching field (the sensing layer) will remain unchanged, while the magnetization of the other layer will be set in a defined direction and then be reversed. From the sign of the resulting resistance change in the word line it can be seen whether a ‘0’ or a ‘1’ is stored in the cell at the crossing point the word and the bit line. In an embodiment spin valves with a fixed magnetization direction are used and the data is detected in the other, free magnetic layer. In this case the absolute resistance of the cell is measured. In an embodiment the resistance is measured differentially with respect to a reference cell. This cell is selected by means of a switching element (usually a transistor), which implies that in this case one transistor is required per cell. Besides sensors with one transistor per cell, alternatively sensors without transistors within the cell are considered. The zero-transistor per cell sensor elements in cross-point geometry provide a higher density, but have a somewhat longer read time.

In the array sensor elements may be read-only elements as described with FIG. 7 for constituting a read-only memory. This has the advantage that no electronic circuitry is needed for generating write currents. Alternatively the sensor elements may be read-write elements, such as MRAM elements described with FIG. 8. This has the advantage that the values of the bit locations can be changed using a programming device that has only heating means for heating bit locations to be programmed. In an embodiment the array has a combination of read-only and read-write elements. This has the advantage that specific data in part of the memory cannot be changed accidentally.

FIG. 9 shows an optical programming device. The device has an array of radiation sources 80, for example lasers. An array of lenses 81 is provided for focusing the laser beams on the bit locations. The memory cells at the bit locations have a memory layer 83 that is magnetically programmable, and a reference layer 84 that has a fixed magnetic state. A bit line 85 and a word line 86 are provide for reading the resistance value which is determined by the magnetic states. An magnetic field source 87, such as a coil, is provided for generating an external magnetic field for setting the magnetic state during programming.

During programming, the memory layer 83 is heated by the external heat source 80 to a temperature approaching, or at, the Néel temperature. The external field is used to align the magnetization of the memory layer in the desired direction, which is then fixed as the heat source is removed and the memory layer cools. The Néel temperature of the reference layer lies above that of the memory layer, thus the magnetization of the reference layer cannot easily be reversed, even during the heating of the memory layer.

In an embodiment of the programming device the cells are individually addressable and heated simultaneously to allow high re-programming data rates. This may be achieved by using, for example, an array of individually addressable VCSELs (vertical cavity surface emitting laser), possibly in combination with focusing optics, or a single light source and an array of lenses.

In an embodiment of the programming device a pattern of light spots on the bit locations is generated, for example using a coherent light source and appropriately arranged diffraction gratings. In particular a pattern of light spots is generated via the Talbot effect. Further details about the Talbot effect can be found in the book ‘Classical Optics and its applications’ by Mansuripur, chapter 18, Cambridge University Press; 1st edition (Dec. 15, 2001) ISBN: 0521800935. For selectively blocking the light path to individual memory cells the device has an integrated shutter, which may be a mask. In an embodiment the programming device has a dynamic optical controlling device for irradiating selected bit locations, such as an LCD shutter device or a digital mirror device (DMD), which has an array of microscopic mirrors that are pivotable under control of electronic signals.

An embodiment of the writing device has a scanning unit for scanning the programming surface. The radiation beams are arranged to irradiate a subset of the memory cells. The information plane of bit locations is scanned by moving the beam relative to the memory device to a multitude of programming positions. A number of bit locations are being programmed per programming position. For example the beams may be generated by a linear array of radiation sources. Subsets of bits are programmed either in a collective fashion (sectors) or distributed fashion (e.g. every second or third or fourth bit). This may be determined by the constraints of the channel electronics, or the spatial distribution (pitch) of the heat sources (e.g. VCSELs), focusing optics (e.g. lenses) or memory cells. Such a programming device is suitable for programming a limited number of bit locations, e.g. for writing a serial number or a unique encryption key in a memory device.

A further embodiment of the programming device contains a multitude of programming surfaces for programming a wafer of dies in a single programming step.

FIG. 10 shows memory devices having a heat sink. An integrated heat sink provides additional control of the temperature at the bit locations and neighboring areas of the device.

FIG. 10a shows a memory device having a heat sink layer. Bit locations 101 are to be heated during programming. The device has a heat sink element near the bit locations for reducing heating of bit locations adjacent to a bit location that is heated for programming. The heat sink element is constituted by an additional heat sink layer 103 of a heat conductive material, e.g. a metal layer or a metal compound. The heat sink layer is positioned on top of the device, or below the other layers of the layer stack of the memory cell. The heat sink layer 103 has windows 102 corresponding to the bit locations 101.

FIG. 10b shows a memory device having heat sink elements. Bit locations 101 are to be heated during programming. The device has longitudinal heat sink elements 104 in between rows and/or columns in the array of bit locations, for example metal (or metal compound) stripes manufactured in the same layer as current conductors. The elements are electrically insulated from the memory cells and logic circuitry (e.g. word and bit lines), and provide control (speeding or slowing) to the heating and/or cooling processes by acting as heat conductors.

Although the invention has been mainly explained by embodiments using the TMR effect, any suitable read/write element for interfacing with the magnetic material can be used, e.g. based on coils. Further in the embodiments the radiation source for heating is a laser source, but any suitable radiation source may be used. It is noted, that in this document the verb ‘comprise’ and its conjugations do not exclude the presence of other elements or steps than those listed and the word ‘a’ or ‘an’ preceding an element does not exclude the presence of a plurality of such elements, that any reference signs do not limit the scope of the claims, that the invention may be implemented by means of both hardware and software, and that several ‘means’ or ‘units’ may be represented by the same item of hardware or software. Further, the scope of the invention is not limited to the embodiments, and the invention lies in each and every novel feature or combination of features described above.

1. Memory device comprising an information plane (14) comprising an electro-magnetic material constituting an array of bit locations (31), a magnetic state of said material at a bit location representing the value thereof, and an array of electro-magnetic sensor elements (51) that are aligned with the bit locations, characterized in that the magnetic state of said material is programmable or programmed via a separate writing device (21) for providing at least one beam of radiation for heating the electro-magnetic material at the bit locations to a programming temperature.

2. Device as claimed in claim 1, wherein the device comprises a housing (11) for encapsulating the array of electro-magnetic sensor elements (51), which housing has an interface surface (32) for cooperating with a programming surface (22) of the writing device for receiving said at least one beam.

3. Device as claimed in claim 1, wherein the device comprises a housing (11) for encapsulating the array of electro-magnetic sensor elements (51), which housing has a protective cover (17) for preventing heating bit locations for changing said magnetic state, in particular the protective cover being a sliding cover.

4. Device as claimed in claim 1, wherein the device comprises a heat sink element near the bit locations for reducing heating of bit locations adjacent to a bit location that is heated for programming.

5. Device as claimed in claim 4, wherein the heat sink element is constituted by a pattern of elements of a layer of metal or metal compound, in particular the layer having windows corresponding to the bit locations or longitudinal elements in between rows and/or columns in the array of bit locations.

6. Device as claimed in claim 1, wherein the sensor elements comprise a second magnetic material for constituting a reference layer having a predetermined magnetic state, the second magnetic material having a second Néel temperature that is substantially higher than a first Néel temperature of the electro-magnetic material constituting an array of bit locations (31) for allowing said programming at the programming temperature near the first Néel temperature without affecting the magnetic state the predetermined magnetic state.

7. Device as claimed in claim 1, wherein the electro-magnetic sensor elements (51) comprise read-only sensor elements (60) that are sensitive to, but unable to change, said magnetic state of the electromagnetic material at a working temperature, the working temperature being substantially lower than the programming temperature.

8. Device as claimed in claim 1, wherein the electro-magnetic sensor elements are provided with electrical conductors for conducting a programming current for generating a magnetic field of sufficient strength for setting the magnetic state at the corresponding bit location when heated to the programming temperature.

9. Device as claimed in claim 1, wherein the electro-magnetic sensor elements are provided with electrical conductors for conducting currents, which conductors are provided with current limiting means for preventing the currents generating a magnetic field of sufficient strength for setting the magnetic state at the corresponding bit location or for preventing heating of the electro-magnetic material at the bit locations to the programming temperature, in particular the current limiting means being a limited current conducting capability or a fuse.

10. Writing device for programming a memory device as claimed in claim 1, the writing device comprising a programming surface (22) for cooperating with the information plane (14) of the memory device, and heating means (26) for generating at least one beam of radiation for heating the electromagnetic material at the bit locations to a programming temperature.

11. Writing device as claimed in claim 10, wherein the device comprises means (27) for generating a magnetic field at the programming surface for setting the magnetic state of the electro-magnetic material at the bit locations.

12. Writing device as claimed in claim 10, wherein the heating means (26) comprise means for generating an array of controllable radiation beams from a single radiation source, in particular via a radiation controlling mask.

13. Writing device as claimed in claim 10, wherein the heating means (26) comprise an array of controllable radiation sources, in particular an array of controllable laser elements.

14. Writing device as claimed in claim 10, wherein the heating means (26) comprise means for generating an array of controllable radiation beams from a single coherent light source, in particular the light source cooperating with a diffraction grating.

15. Writing device as claimed in claim 10, wherein the heating means (26) comprise a liquid crystal matrix shutter (LCD), or a digital mirror device (DMD) for controlling the beam.

16. Writing device as claimed in claim 10, wherein the heating means (26) comprise means for scanning the information plane by moving the beam relative to the memory device to a multitude of programming positions, at least one bit location being programmed per programming position.

17. Method of manufacturing a memory device as claimed in claim 1, the method comprising programming the device by
heating the electromagnetic material at the bit locations to a programming temperature via at least one beam of radiation provided by a separate writing device (21), and
setting the magnetic state of the electro-magnetic material at the bit locations according to predefined data

18. Method as claimed in claim 17, wherein the programming is performed before encapsulating the device.
